(19) United States
(12) Patent Application Publication
(10) Pub. No.: US 2013/0023068 A1
(43) Pub. Date: Jan. 24, 2013

(54) MANUFACTURE OF PHOTOVOLTAIC MODULE COMPRISING CELL ASSEMBLY

(71) Applicant: Brendan Dunne, Gardanne (FR)

(72) Inventor: Brendan Dunne, Gardanne (FR)

(73) Assignee: NEXCIS, Rousset (FR)

(21) Appl. No.: 13/637,057

(22) PCT Filed: Mar. 24, 2011
(86) PCT No.: PCT/FR2011/050632

§ 371 Date: Sep. 25, 2012

(30) Foreign Application Priority Data
Mar. 26, 2010 (FR) 1052225

(51) Int. Cl. H01L 31/0203

(52) U.S. Cl. 438/15; 438/66; 257/E31.117

(57) ABSTRACT

The present invention relates to the manufacture of a photovoltaic cell panel, said manufacture comprising the steps of: a) obtaining photovoltaic (PV) films that are each intended for a cell and are placed onto a front surface of a metal substrate; b) applying at least one conductive film (CG, CND) onto each front surface of a photovoltaic film; c) cutting up the substrate (SUB) so as to isolate the cells from each other; and d) encapsulating (ENC) the cells on a common mounting. According to the invention, steps d) and c) are reversed, so step d) relates to encapsulating the front surface of the substrate before step c), cutting the substrate up by the rear surface thereof. Additionally,—in step b), an area of the conductive film is extended over the substrate so that the conductive film simultaneously makes contact with the front surface of the photovoltaic film and the front surface of the substrate, and—in step c), the substrate is cut up so as to avoid short-circuiting between the photovoltaic cells, at least under the above-mentioned area of the conductive film and over a substrate width less than the width of the area.

The present invention relates to the manufacture of a photovoltaic module comprising a photovoltaic cell assembly.

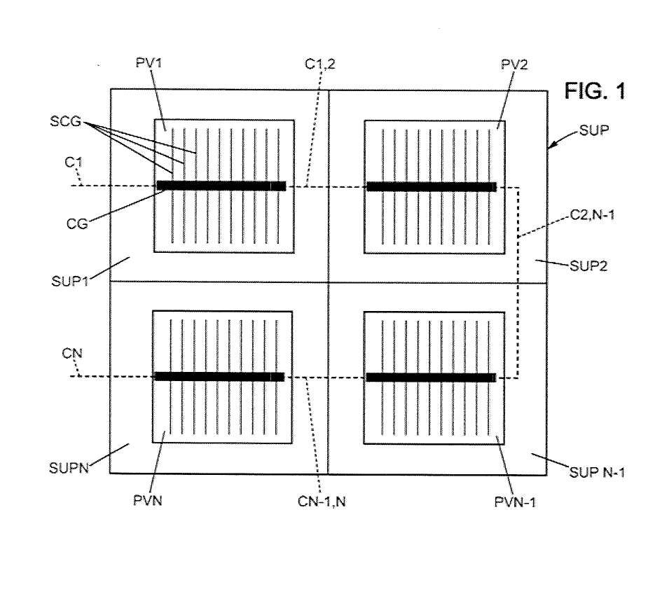

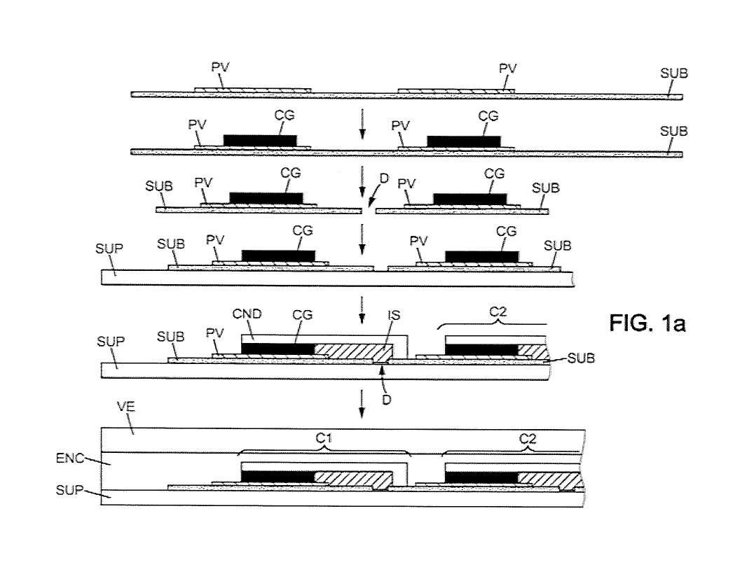

With reference to FIG. 1 depicting a photovoltaic cell assembly, each cell has an active part PV1, PV2, . . . , PVN-1, PVN, resting on a respective support SUP1, SUP2, . . . , SUPN-1, SUPN. Typically, the active part of each cell corresponds to a photodiode having a stack of layers, such as for example:
a matching layer to match to a substrate (often glass, or in the form of a metal foil), that matching layer being molybdenum for example,
an actual active layer with photovoltaic properties (for example, a I-III-V1₂ compound such as copper-(indium, gallium and/or aluminum)-(sulfur and/or selenium), or a compound containing cadmium telluride or amorphous silicon),
and often additional layers (transparent to allow light to interact with the underlying layer with photovoltaic properties) of cadmium sulfide, zinc oxide, etc.

The active part of each cell is generally called “photovoltaic film” here.

Provision is further made to deposit on this film, selectively so as not to obscure the photovoltaic film from the light, a collector grid SCG for charges generated by photovoltaic effect and emanating from the photovoltaic film. Thus, the collector grid has:
deposits (depicted on FIG. 1 in the form of lines, for example screen-printed) made on the upper surface of the photovoltaic film of the cell for collecting the electrons generated by photovoltaic effect, and
a main collector CG connected to these deposits SCG to globally collect the “electricity” generated by the active part PV1.

Thus, the shape of the collector grid SCG and the collector CG is a compromise between the number of incident photons on the photovoltaic film and the number of electrons actually collected. Below, the collector grid SCG and collector CG of a cell are commonly referred to by the general term “collector grid.”

Typically, photovoltaic cells are prepared on a common substrate, then the substrate is cut into so many individual cells. This is followed by a step of creating the connections from each cell and the interconnections between cells, for example through serial connections C1,2; C2,N-1; CN-1,N shown in FIG. 1 as an example. For this step, the valid photovoltaic cells (it being understood that they had been functionally tested beforehand) are again assembled on a common support SUP (made of glass or polymer material) and the aforesaid connections are then created. The photovoltaic module thus obtained may then be connected to an input (via connection C1) and an output (via connection CN).

We refer to FIG. 1a to describe in more detail the successive steps of a manufacturing method for a cell assembly C1, C2 according to prior art. Photovoltaic films PV, each suitable for a future cell C1, C2, are obtained on a substrate SUB (for example, by selective deposition of a photovoltaic film in areas of the substrate where the cells are to be formed, or by selective etching of the deposited film, or by any other known means). A collector layer CG is applied to each PV film in a subsequent step. Then the substrate is cut (Reference D) to form future individual cells. The individual cut pieces are then bonded to a common support SUP. An insulating film IS is then applied, adjacent to the collector layer CG and covering the area of separation D between cells, as shown in FIG. 1a. Finally, a conductive film CND is applied to establish a connection between the front surface of the photovoltaic film PV, via the collector layer CG, and the rear surface of the photovoltaic film PV of the adjacent cell C2, through its substrate SUB. In this example, it is understood that the substrate SUB is conductive, for example a metal. The method may then continue with a step of encapsulating the front surface of the support SUP (supporting the finalized and interconnected cells C1, C2) with, for example, a protective plate VE (of glass for example) bonded to the front surface with the encapsulation material ENC.

However, such a method for cutting and interconnecting cells is long and industrially expensive.

The present invention improves the situation.

It thus proposes to retain the aforesaid photovoltaic films of each cell on a same support, and said support may consist of the original substrate of the photovoltaic films. As will be seen from the embodiments described below, the substrate can be cut but, in particular, the cells are not dissociated, that is to say that their photovoltaic films are not moved with respect to each other during the course of the method according to the invention, and this remains true all the way to the cell interconnection step.

To that end, the present invention relates firstly to a method for manufacturing a panel of photovoltaic cells, comprising the following steps:
a) obtaining photovoltaic films each intended for a cell, arranged on a front surface of a metal substrate,
b) applying at least one conductive film (for example a collector layer, such as a collector grid) on each front surface of a photovoltaic film,
c) cutting the substrate to isolate cells from one another,
d) encapsulating the cells on a common support.

According to the invention, steps d) and c) are reversed, with step d) encapsulating the front surface of the substrate prior to the substrate being cut via its rear surface in step c). Furthermore:
in step b), an area of the conductive film is extended over the substrate such that the conductive film simultaneously makes contact with both the front surface of the photovoltaic film and the front surface of the substrate,

the photovoltaic films of the cells thus being short-circuited between them by the metal substrate in this step b), and
in step c), the substrate is cut so as to avoid short-circuiting between the photovoltaic films, at least under the above-mentioned area of the conductive film and over a substrate width less than the width of the area.

The aforesaid area of the conductive film, combined with the substrate, thus electrically connects the front surface of the photovoltaic film to the rear surface of a photovoltaic film of an adjacent cell.

Thus, the method according to the invention makes it possible to retain the cells on the same support (substrate, then encapsulation of the front surface) throughout their manufacture, which then makes it possible to avoid their mechanical separation from each other, and their subsequent reattachment to a common support thereafter.

The aforesaid conductive film may advantageously comprise a collector grid for charges emanating from the photovoltaic film, which is thus applied to the front surface of the photovoltaic film and is extended over the front surface of the substrate (in the aforesaid area).

Optionally, but not necessarily, the conductive film may further comprise a conductive strip applied to the collector grid and covering the aforesaid area of the collector grid in order to come in contact with the front surface of the substrate.

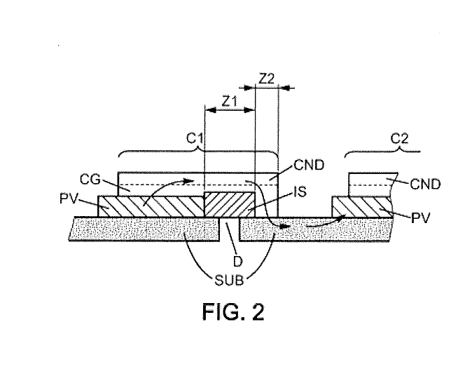

As will be seen in more detail below with reference to FIG. 2, the photovoltaic film (marked PV in this FIG. 2) is at least partially covered by the conductive film (CND, CG). In particular, the conductive film extends beyond the photovoltaic film (PV) into a first area (Z1) and a second consecutive area (Z2) (the second area being further away from the photovoltaic film than the first area). Thus:
the second area (Z2) covers the front surface of the substrate (SUB) and is in contact therewith, and
the substrate (SUB) is cut to have an “empty” space (D), hereinafter referred to as “cut (D)” below the first area (Z1).

There may also be an insulating film (IS), applied prior to step b), and:
adjacent to the photovoltaic film (PV) and of a thickness greater than that of the photovoltaic film, and
intended to be located above the cut (D) of the substrate and under a part of the extension area (Z1) of the conductive film.

More particularly, the insulating film (IS) is intended to be located below the first area (Z1), separating the photovoltaic film (PV) from the second area (Z2), with the insulating film preferably covering one edge of the photovoltaic film (PV), opposite the aforesaid second area (Z2).

In a first embodiment:
the insulating film is applied to at least the front surface of the substrate between steps a) and b), and
the substrate is cut in step c) below the insulating film.

In a first variant:
before step b), the front surface of the substrate is etched, for less than the entire thickness of the substrate, to form a template of the cut in the substrate from step c),
after the etching operation, the insulating film is applied to the front surface of the substrate, at the location of the etching, and
after the encapsulation step, the cutting of the substrate is completed through the entire thickness of the substrate.

In yet another variant:
before step b), the substrate is cut locally only, in an area of the substrate corresponding to the aforesaid first area, and substantially longer than the first area, and
after the encapsulation step, the cutting of the substrate is completed beyond said first area.

Advantageously, there may further be:
a functional testing of the operation of each cell of the panel, and
in the event a tested cell fails, a short-circuiting operation on the faulty cell by filling with conductive material the cut in the substrate made in step c) to form the faulty cell.

Thus, the presence of a faulty cell among the cells of the panel does not affect the future functioning of the entire panel, nor does it require the mechanical removal of the faulty cell from the panel.

The present invention also relates to a panel of photovoltaic cells obtained by implementing the above method. The conductive film of a cell comprises a collector layer for collecting charges emanating from the photovoltaic film, applied to the front surface of the photovoltaic film, the collector layer at least partially covering the photovoltaic film, extending beyond the photovoltaic film over the first and second areas, the second area being further away from the photovoltaic film than the first area. In particular:
said second area covers the front surface of the substrate, it being in contact therewith, and
the substrate has been cut at least below said first area.

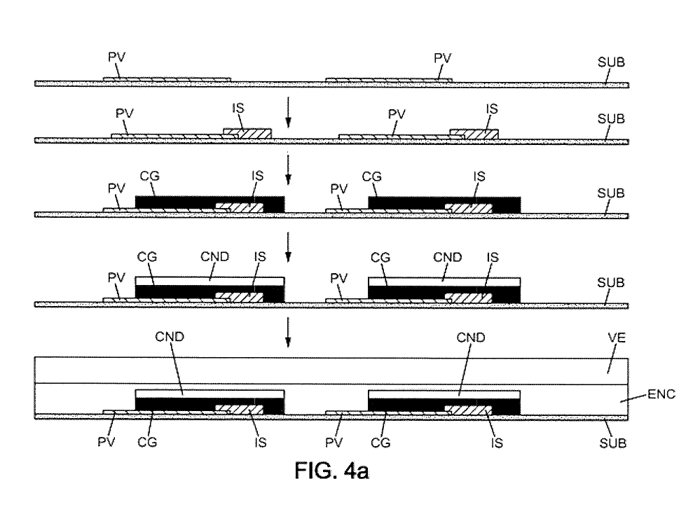

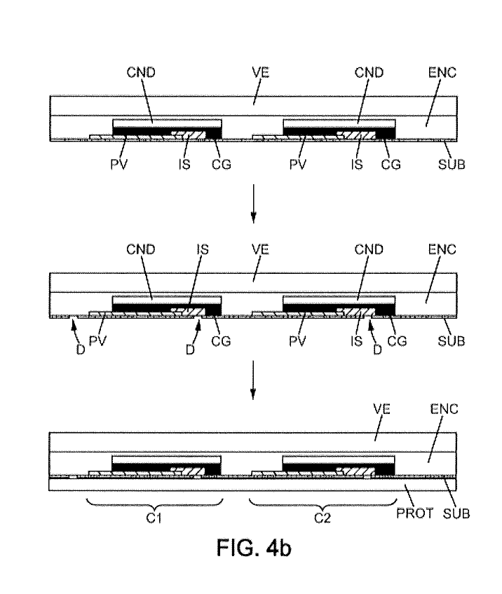

It will thus be understood that this is one of the possible marks of the method according to the invention in the resulting panel. This mark can be seen in particular by comparing FIG. 1a and FIG. 4b described below.

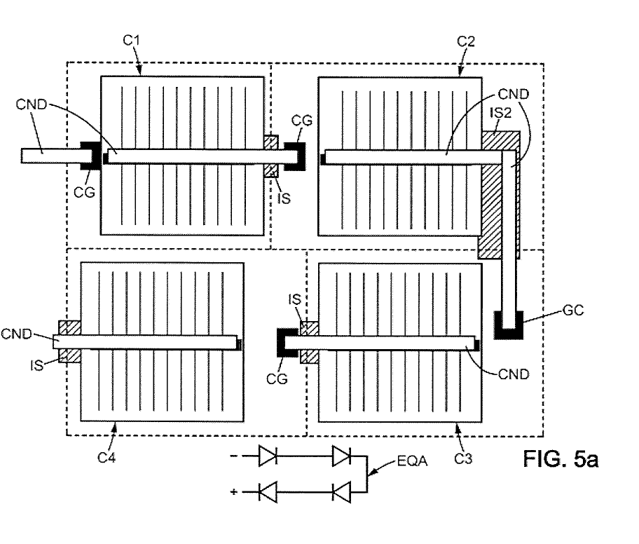

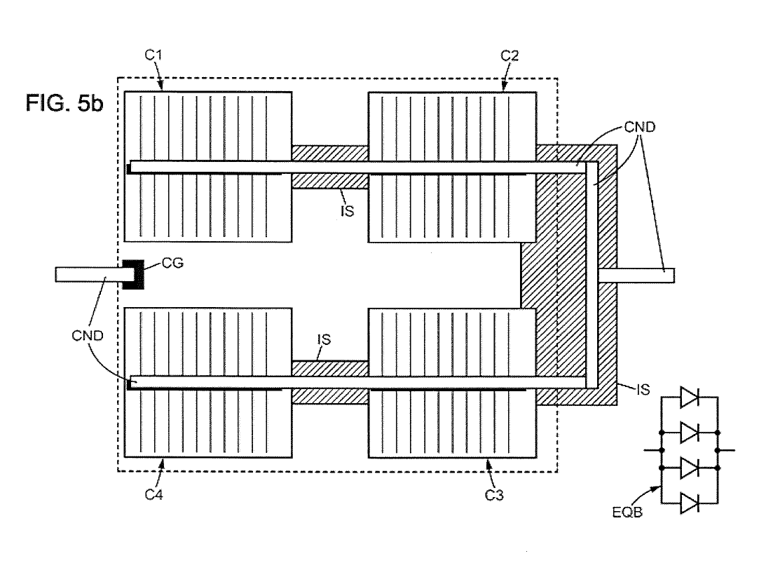

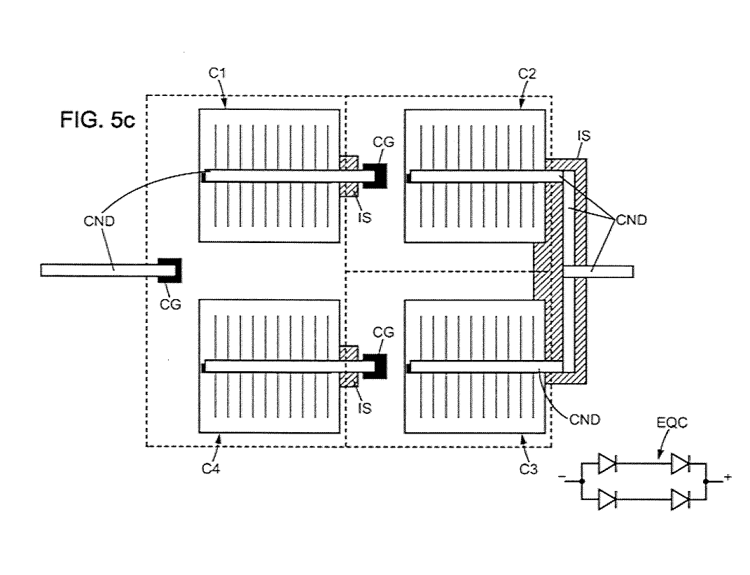

As will be seen also with reference to FIGS. 5a to 5c, the cutting in the substrate may advantageously follow a chosen pattern corresponding to a predetermined wiring diagram for interconnection between cells (series, parallel, series/parallel, etc.). In particular, a cutting pattern completely surrounding a cell may correspond to placing that cell in a series configuration.

Other advantages and features of the invention will become apparent from reading the possible embodiments provided below and reviewing the attached drawings, in which, in addition to FIGS. 1 and 1a discussed above:

FIG. 2 schematically illustrates a partial cross-sectional view of a two-cell assembly according to the invention,

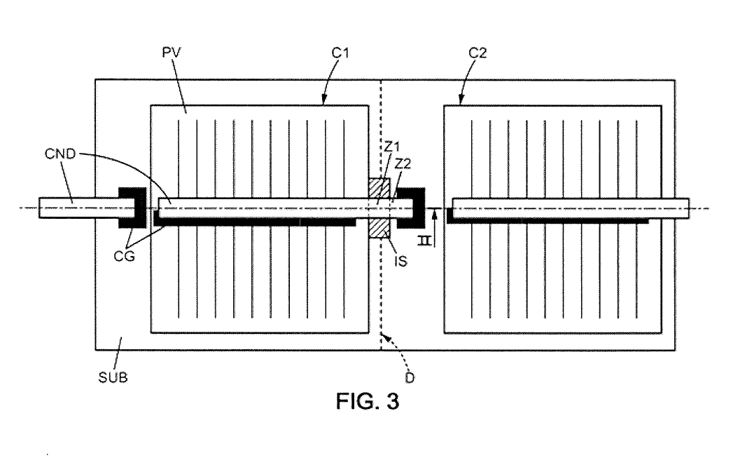

FIG. 3 is a top view of the cells depicted in FIG. 2,

FIGS. 4a and 4b illustrate steps of the method according to the invention, in one embodiment,

FIGS. 5a, 5b, and 5c respectively illustrate possible wiring diagrams for connecting the cells of a cell assembly according to the invention,

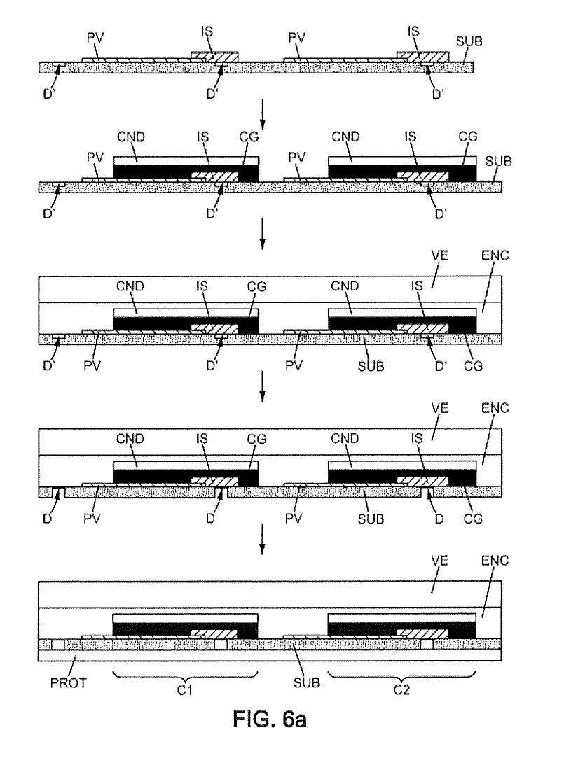

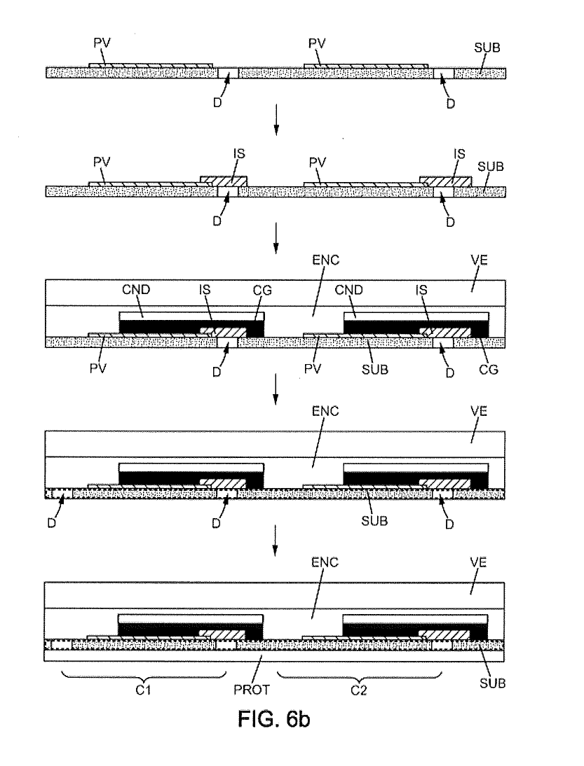

FIGS. 6a and 6b illustrate respective variants of the method from FIGS. 4a and 4b,

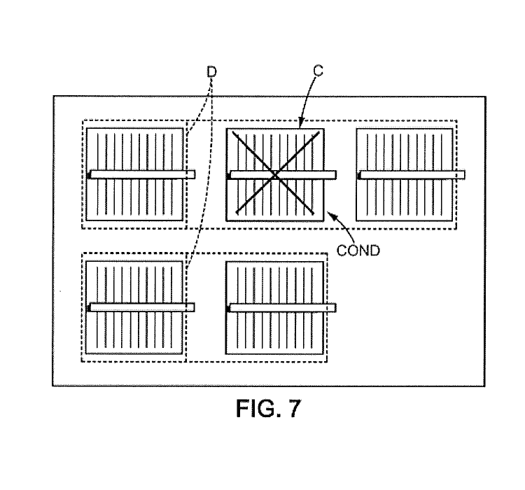

FIG. 7 illustrates an example of short-circuiting one faulty cell C of a cell assembly according to the invention, and

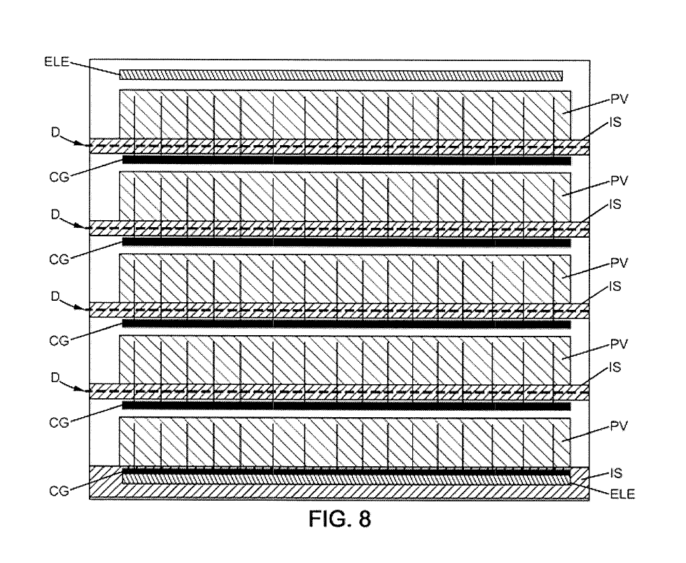

FIG. 8 shows a possible embodiment of a photovoltaic panel.

First we will refer to FIG. 2, which shows a complete cell C1 and an immediately adjacent partial cell C2, resting on a metal substrate denoted SUB. In particular, each cell C1 comprises:
photovoltaic film PV, and
at least one conductive film CND, able to interconnect two cells C1 and C2, as described below.

This conductive film CND at least partially covers the front surface of the photovoltaic film PV and extends beyond the photovoltaic film PV to come in contact with the substrate SUB. In particular, the conductive film CND extends beyond the photovoltaic film PV over:
a first area Z1, followed by
a second area Z2,

the second area Z2 being farther from the photovoltaic film PV than the first area Z1. In fact, as will be seen with reference to FIG. 3, the conductive film CND only partially covers the photovoltaic film PV in order not to obscure the incident light on the photovoltaic film PV.

According to the invention, the cells C1, C2 are retained on a same support common to all the cells, embodied here by the metal substrate SUB, with the photovoltaic films PV of each cell covering the common metal substrate SUB. As will be seen with reference to FIG. 3, the films PV with photovoltaic properties of the cells do not occupy the entire surface of the metal substrate SUB, but only partially cover it, a complementary part of the surface of the substrate SUB being reserved for connections as described below.

In particular, in the cell C1 to be interconnected with the adjacent cell C2, the aforesaid second area Z2 covers the common substrate SUB and comes into contact therewith. Furthermore, the substrate SUB is cut and therefore has an empty space D, particularly below the first area Z1. Without this empty space D, the cell C1 for example is short-circuited by the metal substrate SUB. By cutting the substrate and thus creating that empty space D, an electrical current flows between the respective photovoltaic films PV of the cells C1 and C2 as shown by the arrows in FIG. 2, from the front surface of the film PV of the cell C1, via:
the conductive film CND,
its first area Z1,
its second area Z2,
a part of the metal substrate SUB,

all the way to the rear surface of the film PV of the cell C2.

The empty space D from FIG. 2 can be simply achieved by local etching of the substrate SUB. As will be seen in the examples of cell interconnection described later, such a cut D in the substrate, when made to surround the cell C1, already makes it possible to avoid short-circuiting the cell C1 from the cell C2, for example in a series connection as depicted in FIG. 3.

However, it must be ensured that the photovoltaic film PV does not extend beyond the empty space D and, in particular, will not come into contact with the substrate SUB in proximity to the cell C2 (to the right of the empty space D as depicted in the example of FIG. 2). To that end, there is an insulating film IS, covering the empty space D, separating the film PV from the second area Z2.

As previously indicated, there is usually a collector grid to collect charges emanating from the photovoltaic film PV. Referring again to FIG. 2, the conductive film CND preferably comprises a sub-film CG having such properties for collecting charges emanating from the photovoltaic film PV. An example of a collector grid film will be described in more detail below with reference to FIGS. 4a to 4c.

Thus, as depicted in FIG. 2:
the cut in the substrate SUB can be considered here as having an insulation function between the photovoltaic film PV of the cell C1 and the photovoltaic film PV of the cell C2,
while the extension of the conductive film CND to the second area Z2 has a connection function between the two photovoltaic films PV.

As will be seen below with reference to FIG. 3 and FIGS. 5a to 5c, the cut in the common substrate SUB thus follows a chosen pattern corresponding to a predetermined diagram for electrical interconnection of the cells.

FIG. 3 shows the case of an interconnection of two cells C1 and C2 in a series configuration, the arrow II in said FIG. 3 designating the plane of the cross-section from FIG. 2. The references of FIG. 3 thus designate the same elements as those of FIG. 2. In particular, reference D designates the empty space formed in the substrate SUB. That empty space D is depicted here in the form of a groove thus separating the two cells C1 and C2.

However, the pattern of grooves D for insulation between cells, like the pattern of the extension area Z2 for interconnection between cells, can be chosen based on a predetermined diagram for electrical interconnection of the cells.

FIG. 5a depicts a cutting pattern (dotted lines) appropriate for a series connection of four cells C1 to C4, whose equivalent diagram is denoted EQA. Note that the insulating film of the cell C2, denoted IS2, extends to the groove formed in the substrate between the cells C2 and C3. A cutting pattern completely surrounding a cell (C1, for example) corresponds to a series connection of that cell (C1) with an adjacent cell (C2, for example).

In FIG. 5b, in another possible embodiment, the four illustrated cells C1 to C4 are connected in parallel according to the equivalent diagram EQB in that figure.

In the example of FIG. 5c, the four illustrated cells C1 to C4 are connected according to a parallel/series diagram EQC, the cells C1 and C2 being connected in series, along with the cells C4 and C3.

We will now refer to FIGS. 4a and 4b to describe a possible embodiment of a method for manufacturing a cell assembly C1, C2 depicted for example in FIG. 2.

Photovoltaic films PV are initially obtained on the common metal substrate SUB as shown in the first diagram at the top of FIG. 4a. For example, the substrate SUB may be a thin metal foil (50 to 100 μm) made of steel, copper, or aluminum. A molybdenum matching layer (not shown) can be deposited before the active layer with photovoltaic properties PV is deposited on the substrate. This (or these) deposition(s) can be done, for example, by electrolysis, since the substrate SUB is conductive and can thus accommodate this (or these) electrolysis deposition(s). The photovoltaic layer PV can also be deposited by electrolysis and can be produced in a I-III-VI₂ compound as explained previously. Of course, the present invention applies to any other type of deposition and to any type of photovoltaic material.

Then, in a first step in this embodiment, an insulating film IS is selectively deposited, spanning the photovoltaic film PV and the front surface of the substrate SUB, covering one edge of the photovoltaic film PV and an adjacent portion of the front surface of the substrate SUB. A conductive film, for example in the form of a layer of collector grid CG, is then continuously applied:
to a part of the front surface of the photovoltaic film PV,
to the insulating file IS and,
beyond the insulating film IS, to a part of the front surface of the substrate SUB adjacent to the insulating film IS.

The collector grid film CG (conductive, of course) may itself be sufficient to interconnect the cells. It may be in the form of metallization paste containing liquid silver that can be annealed to dry. Optionally, there is also another conductive film CND that is applied to the front surface of the collector film CG. This film CND may be simply an adhesive metal strip.

The insulating film IS is intended to cover the empty space D previously described with reference to FIG. 2, separating the photovoltaic film PV from the second area Z2 of the conductor CG. Thus, the insulating film IS is in the layers between the photovoltaic film PV and the conductive film CG and/or CND (in the first area Z1 in FIG. 2). In a practical embodiment of the method according to the invention, the insulating film IS preferably partially covers the photovoltaic film PV. In fact, to ensure that the side edge of the film PV is well isolated from the collector grid CG, the insulator IS is deposited completely covering the side edge of the photovoltaic film PV.

At this stage, encapsulation ENC of the front surface (top of FIG. 4a) of the film and substrate assembly is performed. Its purpose is particularly:
firstly, to protect the deposits by applying, for example, a glass plate VE (or one made any other transparent protective material) bonded to an encapsulation material such as, for example, a polymer such as EVA (ethylene vinyl acetate) or PVB (polyvinyl butyral),
secondly, to mechanically hold the assembly as a single block when the step of cutting the substrate is implemented, as described now with reference to FIG. 4b.

As discussed above, particularly with reference to FIG. 3 or FIG. 5a, the substrate may be cut completely around each cell, potentially resulting in mechanical detachment of the cells from each other. Such detachment is avoided due to the encapsulation of the front surface of the assembly, prior to cutting the substrate.

Thus, with reference to FIG. 4b, it can be seen that after bonding the protective plate VE (first top diagram in FIG. 4b), the rear surface of the substrate SUB is left free. The substrate SUB is then cut from its rear surface, to form the empty spaces D, particularly below the insulation IS of each cell. It thus avoids electrical short-circuiting between the cells. This cutting step can be performed with a laser etching technique or simply by sawing, or by chemical etching, or by any other type of technique that allows avoiding damage to at least the collector grid CG above the insulation film IS. Once the substrate is cut and short-circuiting of the cells is avoided, then a protective coating PROT is applied to the rear surface of the substrate SUB.

We refer now to FIG. 6a to describe a variant in which we seek in particular to preserve as much as possible of the insulating film IS and especially the collector grid CG during the substrate SUB cutting step. In particular, here, the substrate is pre-cut through only part of its thickness (regions D′ in FIG. 6a) on its front surface. The subsequent steps for obtaining the photovoltaic films PV, insulation films IS, deposition of collector grids CG, and supplemental conductive films CND are performed, until the encapsulation ENC of the front surface with bonding of the plate VE. Additional cutting is then performed from the rear surface of the substrate SUB, through the entire thickness of the substrate in order to create empty spaces D particularly under the insulating films IS. A protective plate PROT may then be bonded to the rear surface of the fully cut substrate.

For example, in this embodiment, the metal of the common substrate SUB may be partially laser etched from the front surface before the insulating film IS is deposited. Then, the complete cutting of the substrate may be performed at a lower laser power, at the end of the process, thereby reducing the risk of damaging the collector layer CG or the connector strip CND.

The substrate SUB cutting step can thus be critical, particularly in the presence of the collector grid CG, if there is a risk of it being affected by cutting the substrate. Thus, another variant consists of locally cutting the entire thickness of the substrate SUB before depositing the insulation IS and the collector grid CG on the substrate, in order to preserve the grid CG. This variant is shown in FIG. 6b. In the method according to this variant, the substrate SUB is precut locally only in the regions D of the substrate intended to receive the depositions of insulation IS and the collector layer CG. The photovoltaic films PV are obtained as at the beginning of the methods described above with reference to FIGS. 4a and 6a. Then the insulation IS is deposited on the empty spaces D created by locally cutting the substrate. It should be noted here that the material of the insulating film IS can seep into the space D. However, such a possibility does not affect the final functioning of the cell, the purpose of the space D being in fact to isolate the two parts of substrate on either side of said space D. The same comment also applies when the thickness of the substrate is only partially precut (as shown in the first diagram at the top of FIG. 6a). Then, the other steps of depositing the collector grid CG and the conductor CND and the encapsulation ENC are performed with the rear surface of the substrate SUB left free. Once these steps are performed, the substrate can be cut completely through its rear surface, for example around the entire periphery of the cells. In the example in FIG. 6b, the fact that the substrate could be cut around the entirety of each cell C1, C2 is illustrated by dotted lines. There too, once the substrate is completely cut, it is possible to proceed with the encapsulation of the rear surface.

It should also be noted that these method solutions according to FIGS. 6a and 6b retain the possibility of mechanically maintaining all the cells integrally attached to each other until the end of the method.

Thus, the method according to the invention makes it possible to advantageously maintain on the same support, embodied by the substrate SUB, all photovoltaic cells deposited on that support without having to allow for:
systematic individual cutting of the cells,
fastening all cells on a common support,
creation of contacts for each cell,
then, finally, interconnection of the cells.

Here, the substrate SUB serves as a mechanical support for the cells until encapsulation of the front surface of the substrate.

However, in the method according to the invention, with reference now to FIG. 7, the problem may arise of a faulty cell C in the cell assembly. Here, the cells are mechanically attached to each other via the common support, yet the faulty cell C must be electrically eliminated. This difficulty is overcome as follows:
prior to encapsulation of the front surface, a functional testing of the operation of each cell is performed, and
in the event a tested cell fails, a short-circuiting operation is performed on the faulty cell by filling the empty space D below the faulty cell C with a conductive material COND.

Provision can be made, for example, to reweld space D of said cell C, which then has the effect of short-circuiting between its anode and its cathode.

Of course, the present invention is not limited to the embodiment described above as an example; it applies to other variants.

Thus, it will be understood that the invention applies to any type of photovoltaic PV or insulating IS or conductive CG, CND material used in the method according to the invention and is in no way limited to the embodiments given above. Likewise, the geometric shapes of the films depicted in the figures, as well as their respective thicknesses, are presented as illustrative examples only. For example, with reference to FIG. 8, one possible shape of photovoltaic films PV, as a variant of the one shown in FIGS. 1 to 7, consists of a strip extending over the entire width of the substrate. Each film PV is separated from another adjacent film PV by a cut D in the substrate onto which an insulating film IS is applied. A collector grid CG deposited on each film PV comprises conductive fingers coming into contact with the metal substrate immediately after the cut space D. Such an assembly corresponds to a series connection between two cells electrodes ELE (anode and cathode).

Furthermore, the connector strip CND applied to the collector layer CG was described above as an example, and may be optional. In fact, the collector layer CG in contact with the substrate SUB in area Z2 is sufficient to interconnect the front surface of the photovoltaic film PV to the substrate and thence to the rear surface of the photovoltaic film of an adjacent cell. It should be noted also that the collector layer CG of prior art, as depicted in FIG. 1 a, does not have such a function and it simply stops at the insulating film IS. Thus, contrary to the case of the invention as depicted in particular in FIG. 2, areas Z1 and Z2 extending the collector layer beyond the photovoltaic film PV are not found in the prior art. It will thus be understood that this extension of the collector layer CG on the substrate SUB is one of the marks of the method according to the invention in the resulting photovoltaic cell panel.

1. Method for manufacturing a panel of photovoltaic cells, comprising the steps of:
a) obtaining photovoltaic films each intended for a cell, arranged on a front surface of a metal substrate,
b) applying at least one conductive film on each front surface of a photovoltaic film
c) cutting the substrate to isolate cells from one another,
d) encapsulating the cells on a common support,
wherein the steps d) and c) are reversed, with step d) encapsulating the front surface of the substrate prior to the substrate being cut through its rear surface in step c), and wherein:
in step b), an area of the conductive film is extended over the substrate such that the conductive film simultaneously makes contact with both the front surface of the photovoltaic film and the front surface of the substrate,
in step c), the substrate is cut so as to avoid short-circuiting between the photovoltaic films, at least under said area of the conductive film and over a substrate width less than the width of the area,
said area of the conductive film, combined with the substrate, electrically connecting the front surface of the photovoltaic film to the rear surface of a photovoltaic film of an adjacent cell.

2. Method according to claim 1, wherein the conductor film comprises a collector grid for charges emanating from the photovoltaic film, applied to the front surface of the photovoltaic film.

3. Method according to claim 2, wherein the conductive film further comprises a conductive strip applied to the collector grid and covering said area in order to come in contact with the front surface of the substrate.

4. Method according to claim 1, wherein the conductive film at least partially covers the photovoltaic film, extending beyond the photovoltaic film into first and second areas, the second area further away from the photovoltaic film than the first area, and wherein:
said second area covers the front surface of the substrate and is in contact with the substrate, and
the substrate is cut to have an empty space below said first area.

5. Method according to claim 4, wherein an insulating film is applied prior to step b), said insulating film being:
adjacent to the photovoltaic film (PV) and of a thickness greater than that of the photovoltaic film, and
intended to be located above the cut of the substrate and under a part of the extension area of the conductive film.

6. Method according to claim 5, wherein the insulating film is intended to be located below said first area, separating the photovoltaic film from the second area.

7. Method according to claim 6, wherein the insulating film covers one edge of the photovoltaic film, opposite said second area.

8. Method according to claim 6, wherein:
the insulating film is applied to at least the front surface of the substrate between steps a) and b), and
the substrate is cut in step c) below the insulating film.

9. Method according to claim 6, wherein:
before step b), the front surface of the substrate is etched, for less than the entire thickness of the substrate, to form a template of the cut in the substrate from step c),
after the etching operation, the insulating film is applied to the front surface of the substrate, and
after the encapsulation step, the cutting of the substrate is completed through the entire thickness of the substrate.

10. Method according to claim 6, wherein:
before step b), the substrate is cut locally in one area of the substrate corresponding to the aforesaid first area, and substantially longer than the first area, and
after the encapsulation step, the cutting of the substrate is completed beyond said first area.

11. Method according to claim 1, characterized by further comprising:
a functional testing of the operation of each cell of the panel, and
in the event a tested cell fails, a short-circuiting operation on the faulty cell by filling with a conductive material the cut in the substrate made in step c) to form the faulty cell.

12. Panel of photovoltaic cells obtained by implementing the method according to claim 1, the conductive film comprising a collector layer for collecting charges emanating from the photovoltaic film, applied to the front surface of the photovoltaic film,
wherein the collector layer at least partially covers the photovoltaic film, extending beyond the photovoltaic film over the first and second areas, the second area further away from the photovoltaic film than the first area,
and wherein:
said second area covers the front surface of the substrate, it being in contact with said substrate, and
the substrate has been cut at least below said first area.

13. Panel according to claim 12, wherein the cutting in the substrate follows a chosen pattern corresponding to a predetermined wiring diagram for interconnection between cells, and wherein a cutting pattern surrounding a cell corresponds to placing said cell in a series configuration.
